(19) United States
(12) Patent Application Publication
(10) Pub. No.: US 2026/0190542 A1
(43) Pub. Date: Jul. 2, 2026

(54) FULL-COLOR MICROLED DISPLAY DEVICE AND FABRICATION METHOD THEREFOR

(71) Applicant: SUZHOU HAN HUA SEMICONDUCTOR CO., LTD., Suzhou (CN)

(72) Inventors: Xianfeng Ni, Suzhou (CN); Qian Fan, Suzhou (CN)

(73) Assignee: SUZHOU HAN HUA SEMICONDUCTOR CO., LTD., Suzhou (CN)

(21) Appl. No.: 19/414,546

(22) Filed: Dec. 10, 2025

(30) Foreign Application Priority Data
Dec. 31, 2024 (CN) 202411981595.3

(51) Int. Cl. H10H 20/813; H10H 20/01; H10H 20/825

(52) U.S. Cl. CPC H10H 20/8131; H10H 20/01335; H10H 20/017; H10H 20/032; H10H 20/034; H10H 20/8252

(57) ABSTRACT

A full-color MicroLED fabrication method comprises the following steps: forming a first component by epitaxially growing a stacked structure of multiple LED layers (blue, green, red) with intermediate N-GaN and heavily-doped PN junction layers on a silicon substrate; performing sequential etching steps to form first, second, and third stepped structures for accessing the respective N-GaN layers of the blue, green, and red LEDs; forming a metal reflective layer and a passivation layer; and disposing first to fourth sub-electrodes on the stepped structures and the reflective layer. A second component is formed by providing a CMOS driver with a bonding layer having through-holes filled with contact electrodes. The first and second components are then bonded by aligning and connecting the corresponding sub-electrodes and contact electrodes. Finally, the silicon substrate, nucleation layer, and buffer layer are removed to complete the device.

### CROSS-REFERENCE TO RELATED APPLICATIONS

This application claims benefit of the filing date of Chinese Patent Application No. 202411981595.3 filed on Dec. 31, 2024, the disclosure of which is hereby incorporated in its entirety by reference.

### TECHNICAL FIELD OF THE INVENTION

The present invention relates to the technical field of semiconductors, and in particular, to a full-color MicroLED display device and a fabrication method therefor.

### BACKGROUND OF THE INVENTION

Gallium nitride (GaN) is a semiconductor material renowned for its excellent electrical properties and thermal stability, making it highly suitable for fabricating high-brightness and high-efficiency MicroLEDs. GaN MicroLEDs have high luminous efficiency, which significantly reduces power consumption while delivering sufficient brightness for full-color displays. Furthermore, their high stability ensures reliable long-term operation with minimal risk of failure, a critical advantage for full-color display equipment intended for extended use.

In the prior art, achieving full-color MicroLED displays often involves fabricating devices on three separate wafers that emit different colors. These wafers with different emission wavelengths are then bonded together to integrate the three colors. However, this approach suffers from a complex process flow, high cost, low yield, and a long production cycle. Alternatively, another method uses a single epitaxial wafer and attempts to achieve full-color display by tuning the emission wavelength through varying the injection current. Nevertheless, the achievable wavelength tuning range of this method is limited, typically covering only from green to red or from cyan to red, resulting in an insufficient color gamut for display applications.

### SUMMARY OF THE INVENTION

Objective of the Invention: To overcome the deficiencies in the prior art, an objective of the present invention is to provide a full-color MicroLED display device. Another objective of the invention is to provide a method for fabricating said full-color MicroLED display device.

To address the aforementioned technical issues, the present invention provides a full-color MicroLED display device, which comprises several groups of display units. Each display unit includes:
a first N-GaN layer, the side of the first N-GaN layer has a first stepped structure;
a blue LED light-emitting layer, covering the upper surface of the non-step area of the first N-GaN layer;
a first P-GaN layer, covering the upper surface of the blue LED light-emitting layer;
a first heavily doped PN junction layer, covering the upper surface of the first P-GaN layer;
a second N-GaN layer, covering the upper surface of the first heavily doped PN junction layer, the side of the second N-GaN layer has a second stepped structure;
a green LED light-emitting layer, covering the upper surface of the non-step area of the second N-GaN layer;
a second P-GaN layer, covering the upper surface of the green LED light-emitting layer;
a second heavily doped PN junction layer, covering the upper surface of the second P-GaN layer;
a third N-GaN layer, covering the upper surface of the second heavily doped PN junction layer, the side of the third N-GaN layer has a third stepped structure;
a red LED light-emitting layer, covering the upper surface of the non-step area of the third N-GaN layer;
a third P-GaN layer, covering the upper surface of the red LED light-emitting layer;
a third heavily doped PN junction layer, covering the upper surface of the third P-GaN layer;
a fourth N-GaN layer, covering the upper surface of the third heavily doped PN junction layer;
a metal reflective layer, covering the upper surface of the fourth N-GaN layer;
a passivation layer, covering the sidewalls of the first N-GaN layer, the blue LED light-emitting layer, the first P-GaN layer, the first heavily doped PN junction layer, the second N-GaN layer, the green LED light-emitting layer, the second P-GaN layer, the second heavily doped PN junction layer, the third N-GaN layer, the red LED light-emitting layer, the third P-GaN layer, the third heavily doped PN junction layer, the fourth N-GaN layer, and the metal reflective layer;
a first electrode, disposed on the first stepped structure and extending away from the first N-GaN layer;
a second electrode, disposed on the second stepped structure and extending away from the first N-GaN layer;
a third electrode, disposed on the metal reflective layer and extending away from the first N-GaN layer;
a fourth electrode, disposed on the third stepped structure and extending away from the first N-GaN layer;
the upper surfaces of the first electrode, the second electrode, the third electrode, and the fourth electrode are on the same level;
a bonding layer, filling the gaps between the first electrode, the second electrode, the third electrode, the fourth electrode, the passivation layer and covering the first electrode, the second electrode, the third electrode, the fourth electrode, the passivation layer;
a CMOS driver, covering the upper surface of the bonding layer and electrically connected to the first electrode, the second electrode, the third electrode, the fourth electrode.

Preferably, the bonding layer comprises a first bonding layer and a second bonding layer sequentially stacked from bottom to top; the portions of the first electrode, the second electrode, the third electrode, and the fourth electrode embedded within the second bonding layer are defined as a first contact electrode, a second contact electrode, a third contact electrode, and a fourth contact electrode, respectively.

Preferably, the first heavily doped PN junction layer comprises a first P⁺-InGaN layer and a first N⁺-InGaN layer sequentially stacked from bottom to top. The first P⁺-InGaN layer has an indium (In) content of 0-10% and is doped with Mg at a concentration of >5×10¹⁹ cm⁻³. The first N⁺-InGaN layer has an In content of 0-10% and is doped with Si at a concentration of >2×10¹⁹ cm⁻³.

Preferably, the second heavily doped PN junction layer comprises a second P⁺-InGaN layer and a second N⁺-InGaN layer sequentially stacked from bottom to top. The second P⁺-InGaN layer has an In content of 0-10% and is doped with Mg at a concentration of >5×10¹⁹ cm⁻³. The second N⁺-InGaN layer has an In content of 0-10% and is doped with Si at a concentration of >2×10¹⁹ cm⁻³.

Preferably, the third heavily doped PN junction layer comprises a third P⁺-InGaN layer and a third N⁺-InGaN layer sequentially stacked from bottom to top. The third P⁺-InGaN layer has an In content of 0-10% and is doped with Mg at a concentration of >5×10¹⁹ cm⁻³. The third N⁺-InGaN layer has an In content of 0-10% and is doped with Si at a concentration of >2×10¹⁹ cm⁻³.

Preferably, the first P⁺-InGaN layer has a thickness of 5-20 nm, the first N⁺-InGaN layer has a thickness of 5-20 nm, and the thickness ratio between the first P⁺-InGaN layer and the first N⁺-InGaN layer is 1:1.

Preferably, the second P⁺-InGaN layer has a thickness of 5-20 nm, the second N⁺-InGaN layer has a thickness of 5-20 nm, and the thickness ratio between the second P⁺-InGaN layer and the second N⁺-InGaN layer is 1:1.

Preferably, the third P⁺-InGaN layer has a thickness of 5-20 nm, the third N⁺-InGaN layer has a thickness of 5-20 nm, and the thickness ratio between the third P⁺-InGaN layer and the third N⁺-InGaN layer is 1:1.

Based on the same inventive concept, one of the embodiments further provides a method for fabricating a full-color MicroLED display device, which comprises:
forming a first component, wherein forming the first component comprises:
Step 11: a silicon substrate is provided, and a nucleation layer, a buffer layer, a first N-GaN layer, a blue LED light-emitting layer, a first P-GaN layer, a first heavily-doped PN junction layer, a second N-GaN layer, a green LED light-emitting layer, a second P-GaN layer, a second heavily-doped PN junction layer, a third N-GaN layer, a red LED light-emitting layer, a third P-GaN layer, a third heavily-doped PN junction layer, and a fourth N-GaN layer are sequentially epitaxially grown on the surface of the silicon substrate;
Step 12: a first etching is performed, wherein a portion of each layer above the first N-GaN layer and a portion of the first N-GaN layer are etched in a thickness direction of the first component, thereby forming a first stepped structure at a side edge of the first N-GaN layer;
Step 13: a second etching is performed, wherein a portion of each layer above the second N-GaN layer and a portion of the second N-GaN layer are etched in the thickness direction of the first component, thereby forming a second stepped structure at a side edge of the second N-GaN layer;
Step 14: a third etching is performed, wherein a portion of each layer above the third N-GaN layer and a portion of the third N-GaN layer are etched in the thickness direction of the first component, thereby forming a third stepped structure at a side edge of the third N-GaN layer;
Step 15: a metal reflective layer is formed on the upper surface of the fourth N-GaN layer;
Step 16: a passivation layer is formed, wherein the passivation layer covers sidewalls of the first N-GaN layer, the blue LED light-emitting layer, the first P-GaN layer, the first heavily-doped PN junction layer, the second N-GaN layer, the green LED light-emitting layer, the second P-GaN layer, the second heavily-doped PN junction layer, the third N-GaN layer, the red LED light-emitting layer, the third P-GaN layer, the third heavily-doped PN junction layer, the fourth N-GaN layer, and the metal reflective layer;
Step 17: a first sub-electrode, a second sub-electrode, a third sub-electrode, and a fourth sub-electrode are respectively disposed above the first stepped structure, the second stepped structure, the metal reflective layer, and the third stepped structure;
Step 18: a first bonding layer is formed, wherein the first bonding layer fills gaps among the first sub-electrode, the second sub-electrode, the third sub-electrode, the fourth sub-electrode, and the passivation layer, and covers the metal reflective layer;
Step 19: the first bonding layer is planarized;
forming a second component, wherein forming the second component comprises: Step 21: a CMOS driver is provided, and a second bonding layer is formed over the CMOS driver;
Step 22: the second bonding layer is etched in a thickness direction of the second bonding layer to form four through-holes penetrating through the second bonding layer;
Step 23: a first contact electrode, a second contact electrode, a third contact electrode, and a fourth contact electrode are respectively disposed in the through holes; bonding the first component and the second component, wherein bonding comprises:
Step 31: the second component is horizontally inverted, and the first sub-electrode is aligned and bonded with the first contact electrode, the second sub-electrode is aligned and bonded with the second contact electrode, the third sub-electrode is aligned and bonded with the third contact electrode, and the fourth sub-electrode is aligned and bonded with the fourth contact electrode, thereby respectively forming a first electrode, a second electrode, a third electrode, and a fourth electrode;
Step 32: the silicon substrate, the nucleation layer, and the buffer layer are removed, thereby obtaining the full-color MicroLED display device.

Preferably, after Step 14, P-type Mg doping activation is performed on the first component, with a doping concentration of >5×10¹⁸ cm⁻³.

Working principle: During the fabrication process of a full-color MicroLED display device, three sets of P⁺-InGaN/N⁺-InGaN heavily doped PN junction materials are strategically incorporated, which lays a solid foundation for constructing a high-performance electrode structure. These PN junctions are characterized by their high doping concentrations, which directly results in a significant reduction in the junction width. In general, the width of the junction region of a PN junction is a key factor determining the electron tunneling probability. The wider the junction region, the higher the energy required for electron tunneling and the greater the difficulty. However, in the heavily doped PN junction, due to the increased doping concentration, the junction width is significantly narrowed, enabling electrons to easily pass through this narrow region via tunneling. The quantum tunneling effect is a quantum mechanical phenomenon that allows electrons to pass through the barrier with a certain probability when the energy is insufficient to overcome the barrier. In the heavily doped PN junction, this effect is fully utilized, and electrons can easily achieve reverse conduction, thereby greatly enhancing the conductivity of the electrode. More importantly, this feature brings unprecedented flexibility to electrode fabrication. Since electrons can easily pass through the junction region, when fabricating the electrode, the requirement for the etching depth of the material becomes less stringent. This means that even if there is a certain deviation in the etching depth, the conductivity of the electrode will not be significantly affected, thereby reducing the difficulty and cost of the manufacturing process.

Beneficial effects: compared with the prior art, the present invention has the following remarkable characteristics:

Three light-emitting wavelengths are integrated into one epitaxial wafer, which can be grown in a single epitaxial growth process. There is no need to put the wafer into an epitaxial machine (MOCVD/MBE) for re-growth, nor is there a need to bond and integrate wafers of three different light-emitting wavelengths (RGB) to achieve a variety of light-emitting materials. As a result, the device fabrication process is greatly simplified.

In the electrode fabrication process, there is no need to precisely control the etching depth of the material. This highly simplifies the device fabrication process and improves the manufacturing yield of the device. By adding a heavily doped PN junction layer, due to the higher doping level, the heavily doped PN junction has a smaller junction width, and electrons can tunnel through it to form a reverse conducting current. Therefore, each electrode can be positioned on the thicker N-type material layer after the heavily doped PN junction through material etching. Since the N-type material layer is relatively thick, strict control of the material etching depth is not required.

The three light-emitting wavelength devices in a single wafer can be controlled separately. This allows more precise control over the light-emitting wavelengths, a wider color-tuning range, and an expanded color gamut. Moreover, the shape of each electrode is relatively vertical, and the process steps are simple.

### BRIEF DESCRIPTION OF THE DRAWINGS

In the drawings, each identical or nearly identical component shown in different figures is represented by like reference numerals. For purposes of clarity, not every component in each of the figures is labeled. The figures are not necessarily to scale, emphasis instead being placed upon illustrating various aspects of the techniques and devices described herein.

FIG. 1 is a schematic structural diagram of a product after step 11 of the present invention.

FIG. 2 is a schematic structural diagram of a product after step 14 of the present invention.

FIG. 3 is a schematic structural diagram of a product after step 15 of the present invention.

FIG. 4 is a schematic structural diagram of a product after step 16 of the present invention.

FIG. 5 is a schematic structural diagram of a product after step 17 of the present invention.

FIG. 6 is a top view of the product of step 17 of the present invention.

FIG. 7 is a schematic structural diagram of a product after step 18 of the present invention.

FIGS. 8-9 are schematic structural diagrams of a product after step 21 of the present invention.

FIG. 10 is a schematic structural diagram of a product after step 22 of the present invention.

FIG. 11 is a schematic structural diagram of a product after step 23 of the present invention.

FIG. 12 is a schematic structural diagram of a product after step 32 of the present invention.

Therein, the reference numerals indicate the following:
10—Substrate, 20—Nucleation layer, 30—Buffer layer, 40—First N-GaN layer, 50—Blue LED light-emitting layer, 60—First P-GaN layer, 70—First heavily doped PN junction layer, 71—First P⁺-InGaN layer, 72—First N⁺-InGaN layer, 80—Second N-GaN layer, 90—Green LED light-emitting layer, 100—Second P-GaN layer, 110—Second heavily doped PN junction layer, 111—Second P⁺-InGaN layer, 112—Second N⁺-InGaN layer, 120—Third N-GaN layer, 130—Red LED light-emitting layer, 140—Third P-GaN layer, 150—Third heavily doped PN junction layer, 151—Third P⁺-InGaN layer, 152—Third N⁺-InGaN layer, 160—Fourth N-GaN layer, 170—Metal reflective layer, 180—Passivation layer, 191—First sub-electrode, 192—Second sub-electrode, 193—Third sub-electrode, 194—Fourth sub-electrode, 201—First bonding layer, 202—Second bonding layer, 210—CMOS driver, 220—Through-hole, 231—First contact electrode, 232—Second contact electrode, 233—Third contact electrode, 234—Fourth contact electrode.

### DETAILED DESCRIPTION

Example embodiments will now be described more comprehensively with reference to the accompanying drawings. However, example embodiments can be implemented in various forms and should not be interpreted as being limited to the embodiments described herein. Instead, these embodiments are provided to make this invention more thorough and complete, and to fully convey the concepts of the example embodiments to those skilled in the art. Identical reference numerals in the drawings represent identical or similar structures, so repeated descriptions of them will be omitted.

The terms used to express positions and directions in this invention are illustrated with reference to the drawings. However, modifications can be made as necessary, and all such modifications are included within the scope of protection of this invention. Process parameters (temperatures, pressures, doping concentrations, gas flows, times, thicknesses) are illustrative. Unless explicitly stated otherwise, the order of steps is not limiting and may be altered, combined, or performed in parallel. One skilled in the art may adjust these values without departing from the spirit and scope of the invention.

A method for fabricating a full-color MicroLED display device is provided. The method comprises: preparing a first component; preparing a second component; and bonding the first component and the second component.

Specifically, the first component, the epitaxial structure are prepared using a Metal-Organic Chemical Vapor Deposition (MOCVD) epitaxial growth apparatus, the process comprising the following steps:

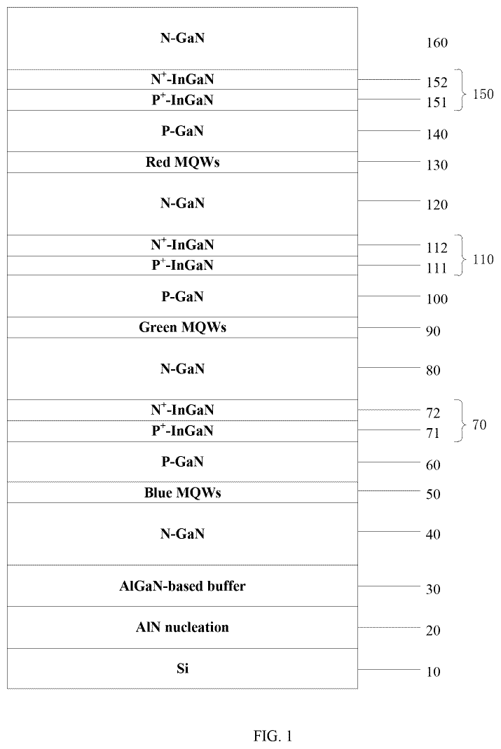

Step 11: A silicon substrate 10 is provided. A nucleation layer 20, a buffer layer 30, a first N-GaN layer 40, a blue LED light-emitting layer 50, a first P-GaN layer 60, a first heavily doped PN junction layer 70, a second N-GaN layer 80, a green LED light-emitting layer 90, a second P-GaN layer 100, a second heavily doped PN junction layer 110, a third N-GaN layer 120, a red LED light-emitting layer 130, a third P-GaN layer 140, a third heavily doped PN junction layer 150, and a fourth N-GaN layer 160 are sequentially epitaxially grown on a surface of the silicon substrate 10, as shown in FIG. 1

Specifically, under a temperature of 950-1150° C. and a pressure of 50-100 torr, a 200 nm AlN nucleation layer 20 is grown on the substrate 10.

Under a temperature of 980-1180° C. and a pressure of 50-100 torr, a 0.2-1 μm AlGaN buffer layer 30 is grown on the nucleation layer 20.

Under a temperature of 1100-1200° C. and a pressure of 200-300 torr, a 0.5-2.0 μm first N-GaN layer 40 is grown on the buffer layer 30.

Under a temperature of 760-800° C. and a pressure of 400-500 torr, a 90-150 nm blue LED light-emitting layer 50 is grown on the first N-GaN layer 40, wherein the blue LED light-emitting layer 50 has a multi-quantum well structure.

Under a temperature of 900-1000° C. and a pressure of 200-300 torr, a 50-100 nm first P-GaN layer 60 is grown on the blue LED light-emitting layer 50.

A first heavily doped PN junction layer 70 is grown on the first P-GaN layer 60. The first heavily doped PN junction layer 70 includes a first P⁺-InGaN layer 71 and a first N⁺-InGaN layer 72 stacked sequentially from bottom to top, wherein an In content is 0-10%. When the In content is 0, the first heavily doped PN junction layer 70 includes a first P⁺-GaN layer 71 and a first N⁺-GaN layer 72 stacked from bottom to top.

Under a temperature of 850-950° C. and a pressure of 400-500 torr, the first P⁺-InGaN layer 71 with a thickness of 5-20 nm is grown on the first P-GaN layer 60. The In content is 0-10%, the dopant is Mg, the doping concentration is >5×10¹⁹ cm⁻³, and the preferred value is 1×10²⁰ cm⁻³.

Under a temperature of 850-950° C. and a pressure of 400-500 torr, the first N⁺-InGaN layer 72 with a thickness of 5-20 nm is grown on the first P⁺-InGaN layer 71. The In content is 0-10%, the dopant is Si, the doping concentration is >2×10¹⁹ cm⁻³, and the preferred value is 3×10¹⁹ cm⁻³, and the thickness ratio of the first P⁺-InGaN layer 71 to the first N⁺-InGaN layer 72 is 1:1.

Under a temperature of 1000-1200° C. and a pressure of 200-300 torr, a second N-GaN layer 80 with a thickness of 0.5-2.0 μm is grown on the first N⁺-InGaN layer 72.

Under a temperature of 742-782° C. and a pressure of 400-500 torr, a green LED light-emitting layer 90 with a thickness of 90-150 nm is grown on the second N-GaN layer 80. The green LED light-emitting layer 90 has a multi-quantum well structure.

Under a temperature of 900-1000° C. and a pressure of 200-300 torr, a second P-GaN layer 100 with a thickness of 50-100 nm is grown on the green LED light-emitting layer 90.

A second heavily doped PN junction layer 110 is grown on the second P-GaN layer 100. The second heavily doped PN junction layer 110 includes a second P⁺-InGaN layer 111 and a second N⁺-InGaN layer 112 stacked sequentially from bottom to top, wherein an In content is 0-10%. When the In content is 0, the second heavily doped PN junction layer 110 includes a second P⁺-GaN layer 111 and a second N⁺-GaN layer 112 stacked from bottom to top.

Under a temperature of 850-950° C. and a pressure of 400-500 torr, the second P⁺-InGaN layer 111 with a thickness of 5-20 nm is grown on the second P-GaN layer 100. The In content is 0-10%, the dopant is Mg, the doping concentration is >5×10¹⁹ cm⁻³, and the preferred value is 1×10²⁰ cm⁻³.

Under a temperature of 850-950° C. and a pressure of 400-500 torr, the second N⁺-InGaN layer 112 with a thickness of 5-20 nm is grown on the second P⁺-InGaN layer 111. The In content is 0-10%, the dopant is Si, the doping concentration is >2×10¹⁹ cm⁻³, the preferred value is 3×10¹⁹ cm⁻³, and the thickness ratio of the second P⁺-InGaN layer to the second N⁺-InGaN layer is 1:1.

Under a temperature of 1000-1200° C. and a pressure of 200-300 torr, a third N-GaN layer 120 with a thickness of 0.5-2.0 μm is grown on the second N⁺-InGaN layer 112.

Under a temperature of 702-742° C. and a pressure of 400-500 torr, a red LED light-emitting layer 130 with a thickness of 90-150 nm is grown on the third N-GaN layer 120. The red LED light-emitting layer 130 has a multi-quantum well structure.

Under a temperature of 900-1000° C. and a pressure of 200-300 torr, a third P-GaN layer 140 with a thickness of 50-100 nm is grown on the red LED light-emitting layer 130.

A third heavily doped PN junction layer 150 is grown on the third P-GaN layer 140. The third heavily doped PN junction layer 150 includes a third P⁺-InGaN layer 151 and a third N⁺-InGaN layer 152 stacked sequentially from bottom to top, wherein an In content is 0-10%. When the In content is 0, the third heavily doped PN junction layer 150 includes a third P⁺-GaN layer 151 and a third N⁺-GaN layer 152 stacked from bottom to top.

Under a temperature of 850-950° C. and a pressure of 400-500 torr, the third P⁺-InGaN layer 151 with a thickness of 5-20 nm is grown on the third P-GaN layer 140. The In content is 0-10%, the dopant is Mg, the doping concentration is >5×10¹⁹ cm⁻³, and the preferred value is 1×10²⁰ cm⁻³.

Under a temperature of 850-950° C. and a pressure of 400-500 torr, the third N⁺-InGaN layer 152 with a thickness of 5-20 nm is grown on the third P⁺-InGaN layer 151. The In content is 0-10%, the dopant is Si, the doping concentration is >2×10¹⁹ cm⁻³, the preferred value is 3×10¹⁹ cm⁻³, and the thickness ratio of the third P⁺-InGaN layer to the third N⁺-InGaN layer is 1:1.

The use of InGaN material for the first heavily doped PN junction layer 70, the second heavily doped PN junction layer 110, and the third heavily doped PN junction layer 150 enables a reduction in forward voltage.

Under a temperature of 1000-1200° C. and a pressure of 200-300 torr, a fourth N-GaN layer 160 with a thickness of 0.5-2.0 μm is grown on the third N⁺-InGaN layer 152.

Three light-emitting wavelengths are integrated within the epitaxial wafer through a single epitaxial growth process. This method eliminates the need for multiple insertions into the MOCVD reactor for regrowth, as well as the bonding and integration of three separate wafers with different light-emitting wavelengths (RGB colors). Consequently, the fabrication processes for related light-emitting materials and devices are greatly simplified.

Step 12: First etching. A portion of each layer on the first N-GaN layer 40 and a portion of the first N-GaN layer 40 are etched along the thickness direction of the first component, resulting in the formation of a first stepped structure on the side edge of the first N-GaN layer 40.

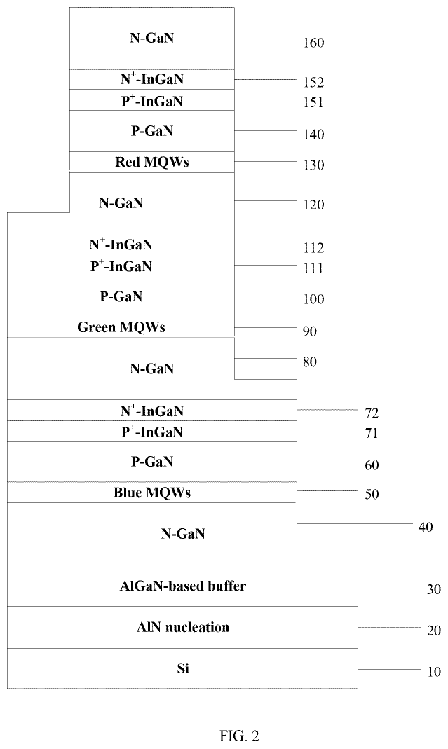

A photoresist is applied to the object obtained in Step 11. Subsequently, a mask is used for exposure and development, and a pattern for etching is formed. An ion etching technique is utilized to etch the epitaxial layer according to the photolithography pattern, by which the unwanted parts are removed. The etching is carried out until the first N-GaN layer 40 is reached, and a first stepped structure is formed on its side edge. As illustrated in FIG. 2, the first stepped structure corresponds to the recessed region formed by partial etching of the first N-GaN layer 40. The thickness of the etched part of the first N-GaN layer 40 is less than its original thickness.

Step 13: Second etching. A portion of each layer on the second N-GaN layer 80 and a portion of the second N-GaN layer 80 are etched along the thickness direction of the first component, resulting in the formation of a second stepped structure on the side edge of the second N-GaN layer 80.

A photoresist is applied to the object obtained in Step 12. Subsequently, a mask is used for exposure and development, and a pattern for etching is formed. An ion etching technique is utilized to etch the epitaxial layer according to the photolithography pattern, by which the unwanted parts are removed. The etching is carried out until the second N-GaN layer 80 is reached, and a second stepped structure is formed on its side edge. As illustrated in FIG. 2, the second stepped structure corresponds to the recessed region formed by partial etching of the second N-GaN layer 80. The thickness of the etched part of the second N-GaN layer 80 is less than its original thickness.

Step 14: Third etching. A portion of each layer on the third N-GaN layer 120 and a portion of the third N-GaN layer 120 are etched along the thickness direction of the first component, resulting in the formation of a third stepped structure on a side edge of the third N-GaN layer 120.

A photoresist is applied to the object obtained in Step 13. Subsequently, a mask is used for exposure and development, and a pattern for etching is formed. An ion etching technique is utilized to etch the epitaxial layer according to the photolithography pattern, by which the unwanted parts are removed. The etching is carried out until the third N-GaN layer 120 is reached, and a third stepped structure is formed on its side edge. As illustrated in FIG. 2, the third stepped structure corresponds to the recessed region formed by partial etching of the third N-GaN layer 120. The thickness of the etched part of the third N-GaN layer 120 is less than its original thickness.

Three rounds of etching are completed, as shown in FIG. 2. The order of steps 12-14 can be interchanged.

After the sidewalls are formed by etching, P-type activation is performed in a nitrogen (N₂) atmosphere at a high temperature of 600-700° C. The formation of the sidewalls facilitates the out-diffusion of hydrogen (H) atoms, thereby activating the Mg dopants. The doping concentration is >5×10¹⁸ cm⁻³.

Step 15: a metal reflective layer 170 is formed on the upper surface of the fourth N-GaN layer 160.

A photoresist is coated on the structure obtained in Step 14, which is then exposed and developed using a mask to expose the fourth N-GaN layer 160.

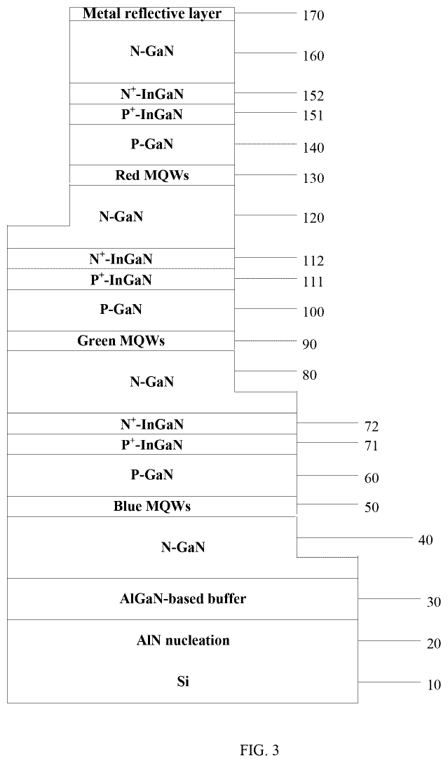

A metal reflective layer 170 with a thickness of 100 nm is formed on the surface of the fourth N-GaN layer 160 using a vacuum electron beam evaporation system, as shown in FIG. 3.

The material for the metal reflective layer 170 may be silver (Ag), aluminum (Al), or gold (Au). These materials possess high reflectivity and can form good adhesion with the fourth N-GaN layer 160.

Step 16: a passivation layer 180 is formed, covering the sidewalls of the first N-GaN layer 40, the blue LED light-emitting layer 50, the first P-GaN layer 60, the first heavily doped PN junction layer 70, the second N-GaN layer 80, the green LED light-emitting layer 90, the second P-GaN layer 100, the second heavily doped PN junction layer 110, the third N-GaN layer 120, the red LED light-emitting layer 130, the third P-GaN layer 140, the third heavily doped PN junction layer 150, the fourth N-GaN layer 160, and the metal reflective layer 170.

The passivation layer 180 is deposited by a chemical vapor deposition (CVD) or physical vapor deposition (PVD) method. Using the CVD method as an example, an aluminum source (TMAI), nitrogen (N₂), and ammonia (NH₃) are used as reaction gases. The deposition is conducted at a temperature of 900-1000° C., with an aluminum source gas flow rate of 100-150 sccm, a nitrogen (N₂) gas flow rate of 15,000-25,000 sccm, and an ammonia (NH₃) gas flow rate of 250-350 sccm, for a reaction time of 4-6 minutes, to obtain a uniform and dense passivation layer 180 with a thickness of 5-50 nm.

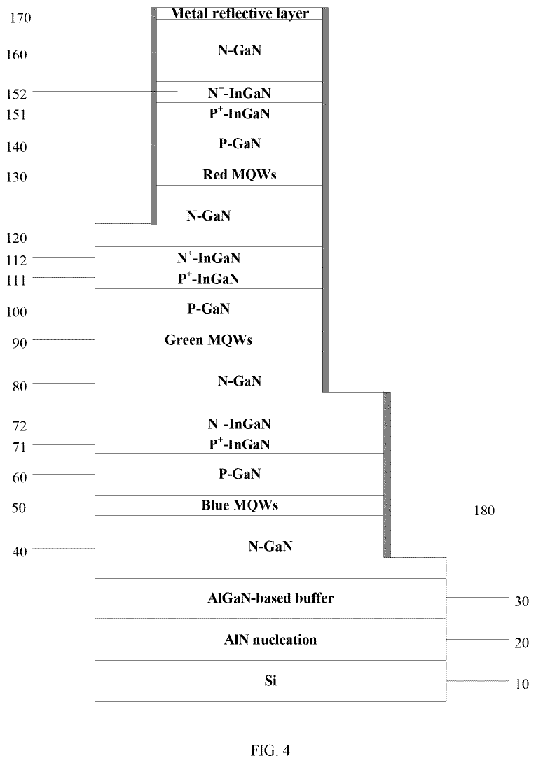

After the AlN passivation layer 180 is formed, photolithography and etching processes are required to form the desired patterns and windows, as shown in FIG. 4.

The primary function of the passivation layer 180 is to protect the MicroLED device from damage caused by the external environment, such as oxidation, moisture, and dust, while simultaneously improving the light extraction efficiency and performance of the MicroLED.

Step 17: a first sub-electrode 191, a second sub-electrode 192, a third sub-electrode 193, and a fourth sub-electrode 194 are respectively disposed above the first stepped structure, the second stepped structure, the metal reflective layer 170, and the third stepped structure.

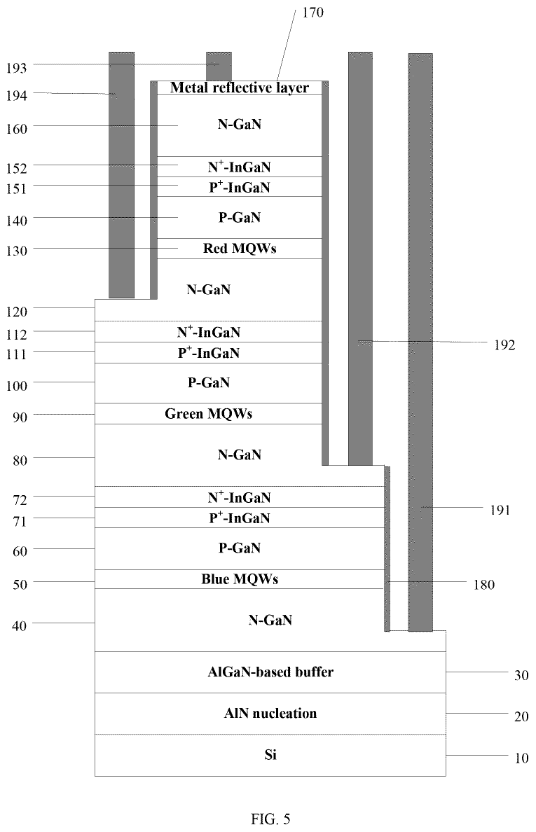

Herein, the first sub-electrode 191 is disposed perpendicular to the first stepped structure and serves as the negative electrode for the blue LED. The second sub-electrode 192 is disposed perpendicular to the second stepped structure and serves as the positive electrode for the blue LED and the negative electrode for the green LED. The third sub-electrode 193 is disposed perpendicular to the metal reflective layer 170 and serves as the positive electrode for the red LED. The fourth sub-electrode 194 is disposed perpendicular to the third stepped structure and serves as the negative electrode for the red LED and the positive electrode for the green LED, as shown in FIG. 5. The electrode material can be gold (Au), platinum (Pt), titanium (Ti), or other metals.

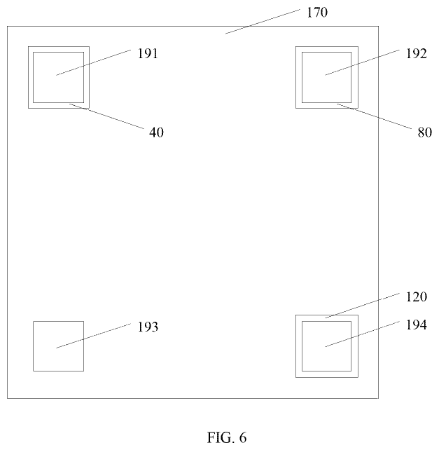

As shown in FIG. 6, a top view of the structure obtained in Step 17, the first sub-electrode 191 is surrounded by the first N-GaN layer 40, the second sub-electrode 192 is surrounded by the second N-GaN layer 80, and the fourth sub-electrode 194 is surrounded by the third N-GaN layer 120. The other regions, as well as the area around the third sub-electrode 193, are the upper surface of the reflective metal layer 170.

Step 18: A first bonding layer 201 is formed. The gaps between the first sub-electrode 191, the second sub-electrode 192, the third sub-electrode 193, the fourth sub-electrode 194, and the passivation layer 180 are filled with the first bonding layer 201, and the metal reflective layer 170 is covered by the first bonding layer 201.

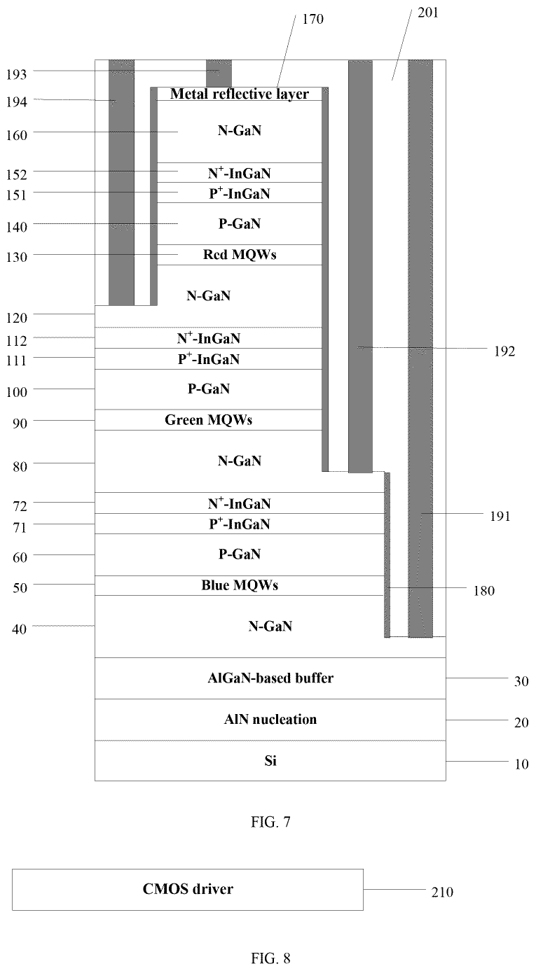

The first bonding layer 201, which is made of SiO₂, is deposited using a Plasma-Enhanced Chemical Vapor Deposition (PECVD) process at a deposition temperature of 300-500° C. The first bonding layer 201 is deposited to fill the gaps between the first sub-electrode 191, the second sub-electrode 192, the third sub-electrode 193, the fourth sub-electrode 194, and the passivation layer 180, and to cover the metal reflective layer 170, as shown in FIG. 7.

Step 19: The first bonding layer 201 is planarized.

Chemical mechanical polishing (CMP) or other planarization techniques are used to improve the surface quality of the first bonding layer 201. Ensure that the top surfaces of the first electrode, second electrode, third electrode, and fourth electrode are on the same level.

Specifically, the second component is prepared to form a CMOS driving circuit, including the following steps:

Step 21: A CMOS driver 210 is provided, and a second bonding layer 202 is formed above the CMOS driver 210.

A second bonding layer 202 is deposited by a PECVD process at a temperature of 300-500° C. The second bonding layer 202, with a thickness of 0.1-1 μm and composed of SiO₂, is formed as shown in FIGS. 8-9.

Step 22: The second bonding layer 202 is etched along its thickness direction to form four through-holes 220 penetrating the second bonding layer.

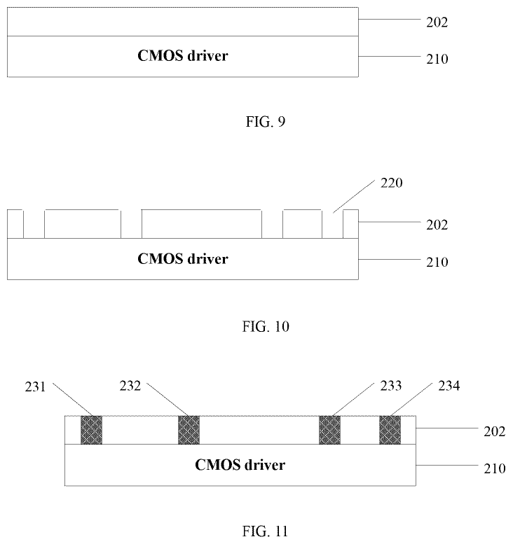

A photoresist is applied to the upper surface of the second bonding layer 202, and exposure and development are performed using a mask to form the pattern to be etched. Ion etching technology is then used to etch the second bonding layer 202 according to the photolithography pattern, forming four through-holes 220 that penetrate the second bonding layer 202, as shown in FIG. 10.

Step 23: A first contact electrode 231, a second contact electrode 232, a third contact electrode 233, and a fourth contact electrode 234 are respectively placed in the through-holes 220, as shown in FIG. 11.

Specifically, bonding the first component and the second component comprises the following steps:

Step 31: The second component is horizontally transposed. The first sub-electrode 191 is aligned and bonded to the first contact electrode 231, the second sub-electrode 192 is aligned and bonded to the second contact electrode 232, the third sub-electrode 193 is aligned and bonded to the third contact electrode 233, and the fourth sub-electrode 194 is aligned and bonded to the fourth contact electrode 234, thereby respectively forming the first electrode, the second electrode, the third electrode, and the fourth electrode.

Using alignment equipment such as microscopes and laser alignment systems, the first sub-electrode 191 and the first contact electrode 231, the second sub-electrode 192 and the second contact electrode 232, the third sub-electrode 193 and the third contact electrode 233, and the fourth sub-electrode 194 and the fourth contact electrode 234 on the first bonding layer 201 (first sub-electrode 191, second sub-electrode 192, third sub-electrode 193, fourth sub-electrode 194) and the second bonding layer 202 (first contact electrode 231, second contact electrode 232, third contact electrode 233, fourth contact electrode 234) are aligned. The first component and the second component are then bonded at a temperature below 350° C.

Step 32: The silicon substrate 10, the nucleation layer 20, and the buffer layer 30 are removed, thereby obtaining the full-color MicroLED display device.

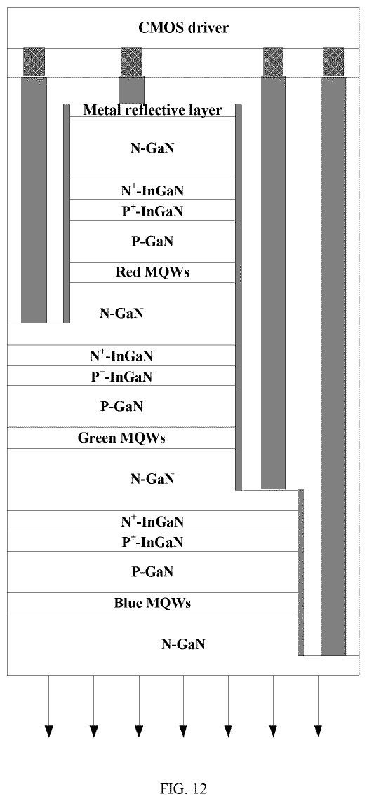

A chemical solution or physical method, such as laser lift-off (LLO) or mechanical grinding, is employed to remove the silicon substrate 10. During this removal process, the nucleation layer 20 and the buffer layer 30 are also removed simultaneously, resulting in the final full-color MicroLED display device, as shown in FIG. 12.

The devices with three distinct emission wavelengths (blue, green, and red) can be controlled independently, enabling a display with a wider color gamut. The emitted tricolor light is output through the first N-GaN layer 40. The red light is not absorbed by the green and blue light-emitting layers, and the green light is not absorbed by the blue light-emitting layer, resulting in relatively high light extraction efficiency.

### Example 1

A method for preparing a full-color MicroLED display device, comprising the following steps:

The fabrication of the first component, the epitaxial structure, can be accomplished using a MOCVD epitaxial growth device. The steps are as follows:

Step 11, Provide a silicon substrate 10, and sequentially grow on the surface of the silicon substrate 10 a nucleation layer 20, a buffer layer 30, a first N-GaN layer 40, a blue LED light-emitting layer 50, a first P-GaN layer 60, a first heavily doped PN junction layer 70, a second N-GaN layer 80, a green LED light-emitting layer 90, a second P-GaN layer 100, a second heavily doped PN junction layer 110, a third N-GaN layer 120, a red LED light-emitting layer 130, a third P-GaN layer 140, a third heavily doped PN junction layer 150, and a fourth N-GaN layer 160, as shown in FIG. 1.

Specifically, a 200 nm AlN nucleation layer 20 is grown on the substrate 10 at a temperature of 1100° C. and a pressure of 50 torr.

A 1 μm AlGaN buffer layer 30 is grown on the nucleation layer 20 at a temperature of 1180° C. and a pressure of 75 torr.

A 0.5 μm first N-GaN layer 40 is grown on the buffer layer 30 at a temperature of 1150° C. and a pressure of 200 torr.

A 90 nm blue LED multi-quantum well light-emitting layer 50 is grown on the first N-GaN layer 40 under a temperature of 780° C. and a pressure of 400 torr.

A 50 nm first P-GaN layer 60 is grown on the blue LED light-emitting layer 50 at a temperature of 950° C. and a pressure of 200 torr.

A 10 nm first P⁺-InGaN layer 71 is grown on the first P-GaN layer 60 at a temperature of 900° C. and a pressure of 400 torr. The In content is 4%, the dopant is Mg, and the doping concentration is 1× 10²⁰ cm⁻³

A 10 nm first N⁺-InGaN layer 72 is grown on the first P⁺-InGaN layer 71 at a temperature of 900° C. and a pressure of 400 torr. The In content is 4%, the dopant is Si, and the doping concentration is 3×10¹⁹ cm⁻³.

A 0.5 μm second N-GaN layer 80 is grown on the first N⁺-InGaN layer 72 at a temperature of 1150° C. and a pressure of 200 torr.

A 90 nm green LED light-emitting layer 90 is grown on the second N-GaN layer 80 at a temperature of 762° C. and a pressure of 400 torr.

A 50 nm second P-GaN layer 100 is grown on the green LED light-emitting layer 90 at a temperature of 950° C. and a pressure of 200 torr.

A 10-nm second P⁺-InGaN layer 111 is grown on the second P-GaN layer 100 at a temperature of 900° C. and a pressure of 400 torr, with an In content of 4%, a dopant of Mg, and a doping concentration of 1×10²⁰ cm⁻³.

A 10-nm second N⁺-InGaN layer 112 is grown on the second P⁺-InGaN layer 111 at a temperature of 900° C. and a pressure of 400 torr, with an In content of 4%, a dopant of Si, and a doping concentration of 3×10¹⁹ cm⁻³.

A 0.5-μm third N-GaN layer 120 is grown on the second N⁺-InGaN layer 112 at a temperature of 1150° C. and a pressure of 200 torr.

A 90-nm red LED light-emitting layer 130 is grown on the third N-GaN layer 120 at a temperature of 722° C. and a pressure of 400 torr.

A 50-nm third P-GaN layer 140 is grown on the red LED light-emitting layer 130 at a temperature of 950° C. and a pressure of 200 torr.

A 10-nm third P⁺-InGaN layer 151 is grown on the third P-GaN layer 140 at a temperature of 900° C. and a pressure of 400 torr, with an In content of 4%, a dopant of Mg, and a doping concentration of 1×10²⁰ cm⁻³.

A 10-nm third N⁺-InGaN layer 152 is grown on the third P⁺-InGaN layer 151 at a temperature of 900° C. and a pressure of 400 torr, with an In content of 4%, a dopant of Si, and a doping concentration of 3×10¹⁹ cm⁻³.

The first heavily doped PN junction layer 70, the second heavily doped PN junction layer 110, and the third heavily doped PN junction layer 150 comprise InGaN material to reduce the forward voltage.

A 0.5-μm fourth N-GaN layer 160 is grown on the third N⁺-InGaN layer 152 at a temperature of 1150° C. and a pressure of 200 torr.

Step 12: First etching. A portion of each layer on the first N-GaN layer 40 and a portion of the first N-GaN layer 40 are etched along the thickness direction of the first component, resulting in the formation of a first stepped structure on the side edge of the first N-GaN layer 40.

A photoresist is applied to the object obtained in Step 11. Subsequently, a mask is used for exposure and development, and a pattern for etching is formed. An ion etching technique is utilized to etch the epitaxial layer according to the photolithography pattern, by which the unwanted parts are removed. The etching is carried out until the first N-GaN layer 40 is reached, and a first stepped structure is formed on its side edge. The thickness of the etched part of the first N-GaN layer 40 is less than its original thickness.

Step 13: Second etching. A portion of each layer on the second N-GaN layer 80 and a portion of the second N-GaN layer 80 are etched along the thickness direction of the first component, resulting in the formation of a second stepped structure on the side edge of the second N-GaN layer 80.

A photoresist is applied to the object obtained in Step 12. Subsequently, a mask is used for exposure and development, and a pattern for etching is formed. An ion etching technique is utilized to etch the epitaxial layer according to the photolithography pattern, by which the unwanted parts are removed. The etching is carried out until the second N-GaN layer 80 is reached, and a second stepped structure is formed on its side edge. The thickness of the etched part of the second N-GaN layer 80 is less than its original thickness.

Step 14: Third etching. A portion of each layer on the third N-GaN layer 120 and a portion of the third N-GaN layer 120 are etched along the thickness direction of the first component, resulting in the formation of a third stepped structure on a side edge of the third N-GaN layer 120.

A photoresist is applied to the object obtained in Step 13. Subsequently, a mask is used for exposure and development, and a pattern for etching is formed. An ion etching technique is utilized to etch the epitaxial layer according to the photolithography pattern, by which the unwanted parts are removed. The etching is carried out until the third N-GaN layer 120 is reached, and a third stepped structure is formed on its side edge. The thickness of the etched part of the third N-GaN layer 120 is less than its original thickness.

Three rounds of etching are completed, as shown in FIG. 2.

After the sidewall is formed through etching, P-type activation is carried out in an N₂ atmosphere at a high temperature of 650° C. The formation of the sidewall enables H atoms to diffuse from it, thereby activating Mg doping, with a doping concentration >5×10¹⁸ cm⁻³.

In step 15, a metal reflective layer 170 is formed on the upper surface of the fourth N-GaN layer 160.

A photoresist is applied to the product obtained in step 14. Subsequently, exposure and development are performed using a mask, and the fourth N-GaN layer 160 is exposed.

A 100 nm metal reflective layer 170 is formed on the surface of the fourth N-GaN layer 160 by means of a vacuum electron beam evaporation device, as shown in FIG. 3.

The metal reflective layer 170 is made of aluminum (Al), which exhibits high reflectivity and can form good adhesion with the fourth N-GaN layer 160.

In step 16, a passivation layer 180 is formed to cover the sidewalls of the first N-GaN layer 40, the blue LED light-emitting layer 50, the first P-GaN layer 60, the first heavily doped PN junction layer 70, the second N-GaN layer 80, the green LED light-emitting layer 90, the second P-GaN layer 100, the second heavily doped PN junction layer 110, the third N-GaN layer 120, the red LED light-emitting layer 130, the third P-GaN layer 140, the third heavily doped PN junction layer 150, the fourth N-GaN layer 160, and the metal reflective layer 170.

The CVD method is employed, with trimethylaluminum (TMAl) used as the aluminum source, nitrogen (N₂), and ammonia (NH₃) as reaction gases. A deposition temperature of 950° C., an aluminum source gas flow rate of 120 sccm, a nitrogen (N₂) gas flow rate of 20000 sccm, an ammonia (NH₃) gas flow rate of 300 sccm, and a reaction time of 5 min are set, by which a uniform and dense 50 nm passivation layer 180 is obtained.

After the AlN passivation layer 180 has been formed, photolithography and etching processes are required to create the desired patterns and windows, as shown in FIG. 4.

In step 17, a first sub-electrode 191, a second sub-electrode 192, a third sub-electrode 193, and a fourth sub-electrode 194 are respectively positioned above the first stepped structure, the second stepped structure, the metal reflective layer 170, and the third stepped structure.

The first sub-electrode 191 is arranged perpendicular to the first stepped structure and is used as the negative electrode of the blue LED. The second sub-electrode 192 is arranged perpendicular to the second stepped structure and functions as the positive electrode of the blue LED and the negative electrode of the green LED. The third sub-electrode 193 is arranged perpendicular to the metal reflective layer 170 and serves as the positive electrode of the red LED. The fourth sub-electrode 194 is arranged perpendicular to the third stepped structure and is used as the negative electrode of the red LED and the positive electrode of the green LED, as shown in FIG. 5. The electrode material is titanium (Ti).

As shown in FIG. 6, which presents the top view of the object obtained in step 17, it can be observed that the first sub-electrode 191 is surrounded by the first N-GaN layer 40, the second sub-electrode 192 is surrounded by the second N-GaN layer 80, and the fourth sub-electrode 194 is surrounded by the third N-GaN layer 120. The other regions, as well as the area around the third sub-electrode 193, are the upper surface of the reflective metal layer 170.

Step 18: A first bonding layer 201 is formed. The gaps between the first sub-electrode 191, the second sub-electrode 192, the third sub-electrode 193, the fourth sub-electrode 194, and the passivation layer 180 are filled by the first bonding layer, and the metal reflective layer 170 is covered by it.

A first bonding layer 201 made of SiO₂ is deposited using a PECVD process at a deposition temperature of 350° C. The deposition is carried out in the gaps between the first sub-electrode 191, the second sub-electrode 192, the third sub-electrode 193, the fourth sub-electrode 194, and the passivation layer 180, and the metal reflective layer 170 is covered by the first bonding layer 201, as shown in FIG. 7.

Step 19. The first bonding layer is planarized.

Chemical mechanical polishing (CMP) planarization technique is employed to improve the surface quality of the first bonding layer 201.

A second component is prepared to form a CMOS drive circuit, which includes the following steps:

Step 21. A CMOS driver 210 is provided, and a second bonding layer 202 is formed over the CMOS driver 210.

As shown in FIGS. 8-9, the second bonding layer 202 is deposited by the PECVD process at 350° C. to form a 0.5 μm second bonding layer 202.

Step 22. The second bonding layer 202 is etched along its thickness direction to form four through-holes 220 that penetrate the second bonding layer

A photoresist is coated on the upper surface of the second bonding layer 202. Then, the photoresist is exposed and developed using a mask to form a pattern for etching. The second bonding layer 202 is etched using an ion etching technique according to the photolithography pattern to form four through-holes 220 that penetrate the second bonding layer 202, as shown in FIG. 10.

Step 23. A first contact electrode 231, a second contact electrode 232, a third contact electrode 233, and a fourth contact electrode 234 are respectively placed in the through-holes 220, as shown in FIG. 11.

Bonding of the first component and the second component is carried out through the following steps:

Step 31: The second component is horizontally repositioned. Alignment for bonding is performed between the first sub-electrode 191 and the first contact electrode 231, the second sub-electrode 192 and the second contact electrode 232, the third sub-electrode 193 and the third contact electrode 233, and the fourth sub-electrode 194 and the fourth contact electrode 234. As a result, the first electrode, the second electrode, the third electrode, and the fourth electrode are respectively formed.

Alignment of the first sub-electrode 191 and the first contact electrode 231, the second sub-electrode 192 and the second contact electrode 232, the third sub-electrode 193 and the third contact electrode 233, as well as the fourth sub-electrode 194 and the fourth contact electrode 234 (where the first, second, third, and fourth sub-electrodes 191, 192, 193, 194 are on the first bonding layer 201, and the first, second, third, and fourth contact electrodes 231, 232, 233, 234 are on the second bonding layer 202) is conducted using a microscope. Subsequently, low-temperature bonding of the first component and the second component is carried out at a temperature below 350° C.

Step 32: The silicon substrate 10, the nucleation layer 20, and the buffer layer 30 are removed to obtain the full-color MicroLED display device.

Removal of the silicon substrate 10 is achieved using a chemical solution. During this removal process, the nucleation layer 20 and the buffer layer 30 are also removed simultaneously, resulting in a full-color MicroLED display device, as shown in FIG. 12.

### Example 2

This example follows the same process steps as Example 1, with the difference lying in the growth of the heavily doped PN junction layers. For the growth of the first heavily doped PN junction layer 70, a 10 nm first P⁺-GaN layer 71 is grown on the first P-GaN layer 60 at a temperature of 900° C. and a pressure of 400 torr. The In content is 0%, the dopant is Mg, and the doping concentration is 1×10²⁰ cm⁻³.

A 10 nm first N⁺-GaN layer 72 is grown on the first P⁺-GaN layer 71 at a temperature of 900° C. and a pressure of 400 torr. The In content is 0%, the dopant is Si, and the doping concentration is 3×10¹⁹ cm⁻³.

For the growth of the second heavily doped PN junction layer 110, a 10 nm second P⁺-GaN layer 111 is grown on the second P-GaN layer 100 at a temperature of 900° C. and a pressure of 400 torr. The In content is 0%, the dopant is Mg, and the doping concentration is 1× 10²⁰ cm⁻³.

A 10 nm second N⁺-GaN layer 112 is grown on the second P⁺-GaN layer 111 at a temperature of 900° C. and a pressure of 400 torr. The In content is 0%, the dopant is Si, and the doping concentration is 3×10¹⁹ cm⁻³.

For the growth of the third heavily doped PN junction layer 150, a 10 nm third P⁺-GaN layer 151 is grown on the third P-GaN layer 140 at a temperature of 900° C. and a pressure of 400 torr. The In content is 0%, the dopant is Mg, and the doping concentration is 1×10²⁰ cm⁻³.

A 10 nm third N⁺-GaN layer 152 is grown on the third P⁺-GaN layer 151 at a temperature of 900° C. and a pressure of 400 torr. The In content is 0%, the dopant is Si, and the doping concentration is 3×10¹⁹ cm⁻³.

### Example 3

This example follows the same process steps as Example 1, with the difference lying in the growth of the heavily doped PN junction layers. For the growth of the first heavily doped PN junction layer 70, a 10 nm first P⁺-InGaN layer 71 is grown on the first P-GaN layer 60 at a temperature of 900° C. and a pressure of 400 torr. The In content is 10%, the dopant is Mg, and the doping concentration is 1×10²⁰ cm⁻³.

A 10 nm first N⁺-InGaN layer 72 is grown on the first P⁺-InGaN layer 71 at a temperature of 900° C. and a pressure of 400 torr. The In content is 10%, the dopant is Si, and the doping concentration is 3×10¹⁹ cm⁻³.

For the growth of the second heavily doped PN junction layer 110, a 10 nm second P⁺-InGaN layer 111 is grown on the second P-GaN layer 100 at a temperature of 900° C. and a pressure of 400 torr. The In content is 10%, the dopant is Mg, and the doping concentration is 1×10²⁰ cm⁻³.

A 10 nm second N⁺-InGaN layer 112 is grown on the second P⁺-InGaN layer 111 at a temperature of 900° C. and a pressure of 400 torr. The In content is 10%, the dopant is Si, and the doping concentration is 3×10¹⁹ cm⁻³.

For the growth of the third heavily doped PN junction layer 150, a 10 nm third P⁺-InGaN layer 151 is grown on the third P-GaN layer 140 at a temperature of 900° C. and a pressure of 400 torr. The In content is 10%, the dopant is Mg, and the doping concentration is 1×10²⁰ cm⁻³.

A 10 nm third N⁺-InGaN layer 152 is grown on the third P⁺-InGaN layer 151 at a temperature of 900° C. and a pressure of 400 torr. The In content is 10%, the dopant is Si, and the doping concentration is 3×10¹⁹ cm⁻³.

### Comparative Example 1

This example follows the same process steps as Example 1, with the difference lying in the growth of the heavily doped PN junction layers. For the growth of the first heavily doped PN junction layer 70, a 10 nm first P⁺-InGaN layer 71 is grown on the first P-GaN layer 60 at a temperature of 900° C. and a pressure of 400 torr. The In content is 15%, the dopant is Mg, and the doping concentration is 1×10²⁰ cm⁻³.

A 10 nm first N⁺-InGaN layer 72 is grown on the first P⁺-InGaN layer 71 at a temperature of 900° C. and a pressure of 400 torr. The In content is 15%, the dopant is Si, and the doping concentration is 3×10¹⁹ cm⁻³.

For the growth of the second heavily doped PN junction layer 110, a 10 nm second P⁺-InGaN layer 111 is grown on the second P-GaN layer 100 at a temperature of 900° C. and a pressure of 400 torr. The In content is 15%, the dopant is Mg, and the doping concentration is 1×10²⁰ cm⁻³.

A 10 nm second N⁺-InGaN layer 112 is grown on the second P⁺-InGaN layer 111 at a temperature of 900° C. and a pressure of 400 torr. The In content is 15%, the dopant is Si, and the doping concentration is 3×10¹⁹ cm⁻³.

For the growth of the third heavily doped PN junction layer 150, a 10 nm third P⁺-InGaN layer 151 is grown on the third P-GaN layer 140 at a temperature of 900° C. and a pressure of 400 torr. The In content is 15%, the dopant is Mg, and the doping concentration is 1×10²⁰ cm⁻³.

A 10 nm third N⁺-InGaN layer 152 is grown on the third P⁺-InGaN layer 151 at a temperature of 900° C. and a pressure of 400 torr. The In content is 15%, the dopant is Si, and the doping concentration is 3×10¹⁹ cm⁻³.

### Comparative Example 2

This example follows the same process steps as Example 1, with the difference lying in the growth of the heavily doped PN junction layers. For the growth of the first heavily doped PN junction layer 70, a 10 nm first P⁺-InGaN layer 71 is grown on the first P-GaN layer 60 at a temperature of 900° C. and a pressure of 400 torr. The In content is 20%, the dopant is Mg, and the doping concentration is 1×10²⁰ cm⁻³.

A 10 nm first N⁺-InGaN layer 72 is grown on the first P⁺-InGaN layer 71 at a temperature of 900° C. and a pressure of 400 torr. The In content is 20%, the dopant is Si, and the doping concentration is 3×10¹⁹ cm⁻³.

For the growth of the second heavily doped PN junction layer 110, a 10 nm second P⁺-InGaN layer 111 is grown on the second P-GaN layer 100 at a temperature of 900° C. and a pressure of 400 torr. The In content is 20%, the dopant is Mg, and the doping concentration is 1×10²⁰ cm⁻³.

A 10 nm second N⁺-InGaN layer 112 is grown on the second P⁺-InGaN layer 111 at a temperature of 900° C. and a pressure of 400 torr. The In content is 20%, the dopant is Si, and the doping concentration is 3×10¹⁹ cm⁻³.

For the growth of the third heavily doped PN junction layer 150, a 10 nm third P⁺-InGaN layer 151 is grown on the third P-GaN layer 140 at a temperature of 900° C. and a pressure of 400 torr. The In content is 20%, the dopant is Mg, and the doping concentration is 1×10²⁰ cm⁻³.

A 10 nm third N⁺-InGaN layer 152 is grown on the third P⁺-InGaN layer 151 at a temperature of 900° C. and a pressure of 400 torr. The In content is 20%, the dopant is Si, and the doping concentration is 3×10¹⁹ cm⁻³.

The working voltage and luminous efficiency of the display units in the full-color MicroLED display devices of Examples 1-3 and Comparative Examples 1-2 were tested, and the results are shown in Table 1.

TABLE 1

| | Working voltage | |
|---|---|---|
| | of display units | |
| | in MicroLED | Luminous |
| | display devices | efficiency |
| | (Unit: Volt, V) | (Unit: cd/A) |
| Example 1 | Red light: 2.50 | Red light: 5 |
| (In content in the heavily | Green light: 2.65 | Green light: 90 |
| doped PN junction: 4%) | Blue light: 2.75 | Blue light: 20 |
| Example 2 | Red light: 2.55 | Red light: 4.3 |
| (In content in the heavily | Green light: 2.71 | Green light: 85 |
| doped PN junction: 0%) | Blue light: 2.80 | Blue light: 18 |
| Example 3 | Red light: 2.39 | Red light: 4.8 |
| (In content in the heavily | Green light: 2.53 | Green light: 87 |
| doped PN junction: 10%) | Blue light: 2.64 | Blue light: 18 |
| Comparative Example 1 | Red light: 2.35 | Red light: 4.5 |
| (In content in the heavily | Green light: 2.50 | Green light: 76 |
| doped PN junction: 15%) | Blue light: 2.59 | Blue light: 14 |
| Comparative Example 2 | Red light: 2.32 | Red light: 4.2 |
| (In content in the heavily | Green light: 2.47 | Green light: 64 |
| doped PN junction: 20%) | Blue light: 2.56 | Blue light: 10 |

From the data in Table 1, it can be observed that:

When the In content in the P⁺-InGaN layer and N⁺-InGaN layer is within the range of 0-4%, and the In content is relatively low, the energy band structures of the P⁺-InGaN layer and N⁺-InGaN layer remain relatively stable, while the voltage of the full-color MicroLED display unit decreases slightly. An increase in In content improves the luminous efficiency of the display unit to some extent. The luminous efficiency of the display unit is highest when the In content in the heavily doped PN junction is near 4%.

As the In content increases (4-10%), significant changes begin to occur in the energy band structures of the P⁺-InGaN layer and N⁺-InGaN layer. The introduction of In reduces the bandgap of the display unit and increases the ionization ratios of Mg and Si dopants, leading to a reduction in the voltage of the display unit. However, the luminous efficiency becomes slightly lower than that in Example 1.

When the indium content is excessively high (above 15%), the P⁺-InGaN layer and N⁺-InGaN layer exhibit some absorption of the light emitted by the display unit, resulting in a decrease in luminous efficiency. The decline in blue and green light intensities is more pronounced.

While embodiments of the present invention have been illustrated and described above, it is to be understood that they are provided by way of example only and are not to be construed as limiting the present invention. Within the spirit and scope of the invention, those of ordinary skill in the art may make various changes, modifications, substitutions, and alterations to the aforementioned embodiments. All such modifications are intended to be encompassed within the scope of the appended claims.

What is claimed:

1. A method for fabricating a MicroLED display device, comprising:
forming a first component, wherein forming the first component comprises:
providing a silicon substrate; and sequentially epitaxially growing a nucleation layer, a buffer layer, a first N-GaN layer, a blue LED light-emitting layer, a first P-GaN layer, a first heavily-doped PN junction layer, a second N-GaN layer, a green LED light-emitting layer, a second P-GaN layer, a second heavily-doped PN junction layer, a third N-GaN layer, a red LED light-emitting layer, a third P-GaN layer, a third heavily-doped PN junction layer, and a fourth N-GaN layer on the surface of the silicon substrate;
performing a first etching to remove a portion of each layer above the first N-GaN layer and a portion of the first N-GaN layer in a thickness direction of the first component, thereby forming a first stepped structure at a side edge of the first N-GaN layer;
performing a second etching to remove a portion of each layer above the second N-GaN layer and a portion of the second N-GaN layer along the thickness direction of the first component, thereby forming a second stepped structure at a side edge of the second N-GaN layer;
performing a third etching to remove a portion of each layer above the third N-GaN layer and a portion of the third N-GaN layer along the thickness direction of the first component, thereby forming a third stepped structure at a side edge of the third N-GaN layer;
forming a metal reflective layer on the upper surface of the fourth N-GaN layer;
forming a passivation layer covering sidewalls of the first N-GaN layer, the blue LED light-emitting layer, the first P-GaN layer, the first heavily-doped PN junction layer, the second N-GaN layer, the green LED light-emitting layer, the second P-GaN layer, the second heavily-doped PN junction layer, the third N-GaN layer, the red LED light-emitting layer, the third P-GaN layer, the third heavily-doped PN junction layer, the fourth N-GaN layer, and the metal reflective layer;
forming a first sub-electrode, a second sub-electrode, a third sub-electrode, and a fourth sub-electrode above the first stepped structure, the second stepped structure, the metal reflective layer, and the third stepped structure, respectively;
forming a first bonding layer that fills gaps among the first sub-electrode, the second sub-electrode, the third sub-electrode, the fourth sub-electrode, and the passivation layer, and that covers the metal reflective layer;
planarizing the first bonding layer;
forming a second component, wherein forming the second component comprises:
providing a CMOS driver;
forming a second bonding layer over the CMOS driver;
etching the second bonding layer along a thickness direction thereof to form four through-holes penetrating through; and
forming a first contact electrode, a second contact electrode, a third contact electrode, and a fourth contact electrode in the through holes, respectively; and
bonding the first component and the second component, wherein bonding comprises:
inverting the second component horizontally;
aligning and bonding the first sub-electrode to the first contact electrode to form a first electrode, the second sub-electrode to the second contact electrode to form a second electrode, the third sub-electrode to the third contact electrode to form a third electrode, and the fourth sub-electrode to the fourth contact electrode to form a fourth electrode; and
removing the silicon substrate, the nucleation layer, and the buffer layer.

2. The fabrication method according to claim 1, further comprising, after performing the third etching, performing a P-type Mg doping activation on the first component, wherein a doping concentration is greater than 5×10¹⁸ cm⁻³.

3. The fabrication method according to claim 1, wherein the first heavily doped PN junction layer comprises a first P⁺-InGaN layer and a first N⁺-InGaN layer stacked sequentially from bottom to top;
wherein the first P⁺-InGaN layer has an In content of 0-10%, is doped with Mg, and has a doping concentration greater than 5×10¹⁹ cm⁻³; and
wherein the first N⁺-InGaN layer has an In content of 0-10%, is doped with Si, and has a doping concentration greater than 2×10¹⁹ cm⁻³.

4. The fabrication method according to claim 1, wherein the second heavily doped PN junction layer comprises a second P⁺-InGaN layer and a second N⁺-InGaN layer stacked sequentially from bottom to top;
wherein the second P⁺-InGaN layer has an In content of 0-10%, is doped with Mg, and has a doping concentration greater than 5×10¹⁹ cm⁻³; and
wherein the second N⁺-InGaN layer has an In content of 0-10%, is doped with Si, and has a doping concentration greater than 2×10¹⁹ cm⁻³.

5. The fabrication method according to claim 1, wherein the third heavily doped PN junction layer comprises a third P⁺-InGaN layer and a third N⁺-InGaN layer stacked sequentially from bottom to top;
wherein the third P⁺-InGaN layer has an In content of 0-10%, is doped with Mg, and has a doping concentration greater than 5×10¹⁹ cm⁻³; and
wherein the third N⁺-InGaN layer has an In content of 0-10%, is doped with Si, and has a doping concentration greater than 2×10¹⁹ cm⁻³.

6. The fabrication method according to claim 3, wherein the first P⁺-InGaN layer has a thickness of 5-20 nm, the first N⁺-InGaN layer has a thickness of 5-20 nm, and a thickness ratio between the first P⁺-InGaN layer and the first N⁺-InGaN layer is 1:1.

7. The fabrication method according to claim 4, wherein the second P⁺-InGaN layer has a thickness of 5-20 nm, the second N⁺-InGaN layer has a thickness of 5-20 nm, and a thickness ratio between the second P⁺-InGaN layer and the second N⁺-InGaN layer is 1:1.

8. The fabrication method according to claim 5, wherein the third P⁺-InGaN layer has a thickness of 5-20 nm, the third N⁺-InGaN layer has a thickness of 5-20 nm, and a thickness ratio between the third P⁺-InGaN layer and the third N⁺-InGaN layer is 1:1.
